(19) United States
(12) Patent Application Publication
(10) Pub. No.: US 2026/0344097 A1
(43) Pub. Date: Oct. 29, 2026

(54) VIA STRUCTURE FOR MULTI-STACKED CHIPS

(71) Applicant: Taiwan Semiconductor Manufacturing Company, Ltd., Hsinchu (TW)

(72) Inventors: Meng-Fang Hsu, Hsinchu City (TW); Min-Feng Kao, Chiayi City (TW); Hsing-Chih Lin, Tainan City (TW)

(21) Appl. No.: 19/719,297

(22) Filed: Jun. 25, 2026

Related U.S. Application Data
(63) Continuation of application No. 18/603,729, filed on Mar. 13, 2024.

(51) Int. Cl. H10F 39/00; H10W 90/00; H10W 90/20

(52) U.S. Cl. CPC H10F 39/811; H10F 39/026; H10F 39/804; H10W 90/00; H10W 90/297

(57) ABSTRACT

Various embodiments of the present disclosure are directed towards a semiconductor device including a device substrate having a front-side surface opposite a back-side surface. An upper dielectric layer is disposed over the back-side surface. A through substrate via (TSV) extends from the upper dielectric layer through the device substrate. A dummy via is laterally offset from the TSV. A top surface of the dummy via and a top surface of the TSV are co-planar, and a bottom surface of the dummy via is separated from the front-side surface by the device substrate.

### REFERENCE TO RELATED APPLICATION

This Application is a Continuation of U.S. application Ser. No. 18/603,729, filed on Mar. 13, 2024, the contents of which are hereby incorporated by reference in their entirety.

### BACKGROUND

Many modern-day electronic devices (e.g., smartphones, digital cameras, biomedical imaging devices, automotive imaging devices, etc.) comprise semiconductor devices with multi-stacked chips. Chips that are bonded to one another increase the functionality and performance of semiconductor devices like image sensors, memory devices, microprocessors, and the like. Multi-stacked chips result in three dimensional integration for devices that realize compact device footprints.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a semiconductor device comprising an active through substrate via (TSV) and a dummy via.

FIG. 2 illustrates a cross-sectional view of some embodiments of a stacked image sensor having an imaging chip, a device chip, and a logic chip.

FIG. 3 illustrates a top view of some embodiments of the stacked image sensor of FIG. 2 taken along the line A-A′ of FIG. 2.

FIGS. 4, 5, and 6 illustrate cross-sectional views of some embodiments of a device chip comprising an active TSV and a dummy via.

FIG. 7 illustrates a cross-sectional view of some embodiments of a stacked image sensor having an active TSV and a dummy via.

FIG. 8 illustrates a cross-sectional view of some embodiments of a stacked image sensor corresponding to some other embodiments of the stacked image sensors of FIGS. 2 and 7.

FIGS. 9-18 illustrate various views of some embodiments of a method of forming a stacked image sensor comprising a dummy via in a device region and an active TSV in a peripheral region.

FIGS. 19-22 illustrate various cross-sectional views of some other embodiments of a method of forming a stacked image sensor with an active TSV and a dummy via.

FIG. 23 illustrates a flowchart according to some embodiments of a method for forming a stacked image sensor comprising an active TSV within a peripheral region and a dummy via within a device region of a device chip.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Semiconductor devices can be multi-stacked chips where individual semiconductor chips (or dies) are diced from a wafer. Chips of a semiconductor device can include integrated circuits (IC's) that provide various function and capabilities for the semiconductor device. After chips are fabricated and diced, they can be bonded to one another and vertically stacked/interconnected by through substrate vias (TSVs), or through silicon vias. Multi-stacked chips provide compact and high-performance semiconductor devices that combine the functionalities of multiple chips. Semiconductor devices that can benefit from multi-stacked chips include memory devices, image sensors, microprocessors, field-programmable gate arrays, radio frequency devices, power devices, light emitting diode devices, or the like.

For example, a stacked image sensor can include an imaging chip, a device chip, and a logic chip that are vertically stacked, where the device chip is bonded to the imaging chip, and the logic chip is bonded to the device chip. The imaging chip can include a plurality of pixel sensors having photodetectors. The device chip can include pixel devices with reset transistors, source-follower transistors, select transistors or the like that are configured to conduct a readout of accumulated charge from the photodetectors. The logic chip can include a plurality of logic devices that may include transistors, logic gates, or other devices configured as an application-specific integrated circuit (ASIC) which can facilitate downstream signal processing of the charge accumulated by the photodetector that is read out by the device chip.

The stacked image sensor can have a device region (e.g., a middle region of the image sensor) aligned with the plurality of pixel sensors and photodetectors, and a peripheral region at an outer perimeter of the image sensor surrounding the plurality of pixel sensors. TSVs are disposed within the peripheral region and configured to electrically couple the logic chip to the device chip. For example, a bond structure with bond pads can connect the device chip to the logic chip, and the TSVs can provide an electrical connection from the device chip to the logic chip through the bond pads.

Devices with multi-stacked chips can suffer from delamination between chips due to stresses at the center of the chips. For example, while the TSVs can provide structural support at the peripheral region of the image sensor, the logic chip and device chip can experience deformation or delamination in the device region where a substrate layer of the device chip deforms due to stress or a dielectric film between the device chip and the logic chip delaminates.

Various aspects of the present disclosure are directed towards a via structure for multi-stacked chips that include dummy vias. The dummy vias are disposed within a device region of a semiconductor device to provide structural support thereby avoiding inter-chip or inter-layer deformation or delamination. For example, the device chip can include a device substrate and an upper dielectric layer disposed over the device substrate. The device substrate has a front-side surface opposite a back-side surface. An active TSV in the peripheral region is disposed within the device substrate extending from the upper dielectric layer and through the device substrate. A dummy via within the device region is laterally offset from the active TSV and extends from the upper dielectric layer towards the device substrate, wherein the dummy via is separated from the front-side surface of the device substrate. A top surface of the active TSV and the dummy via are substantially co-planar and the active TSV has a first height that is greater than a second height of the dummy via. Furthermore, the active TSV is connected to an active device (e.g., a transistor), and the dummy via is electrically isolated from active devices.

By adding one or more dummy vias within the device region of the device chip, structural support is realized between the logic chip and the device chip without adding through vias in the device region of the device substrate. As such, cross-talk within the device substrate is minimized by avoiding superfluous through vias within the device substrate, space for active devices is maintained within the device region by avoiding TSVs within the device region, and rigidity/stress absorption points are realized within the device region. The one or more dummy vias can reduce or eliminate the risk of inter-chip or inter-layer delamination or deformation caused by stresses within the multi-stack chip caused by mechanical stresses including thermal expansion of the multi-stack chip.

As discussed herein, various methods of forming the active TSV and dummy via are presented. For example, the active TSV and dummy via can be formed with a single photoresist mask and two etches. This process has the benefit of low cost formation of the active TSV and dummy via. In another example, the active TSV and dummy via are formed with two photoresist masks and three etches. This process has the benefit of independent and high-fidelity control of the critical dimensions for the active TSV and dummy via by independent etching processes.

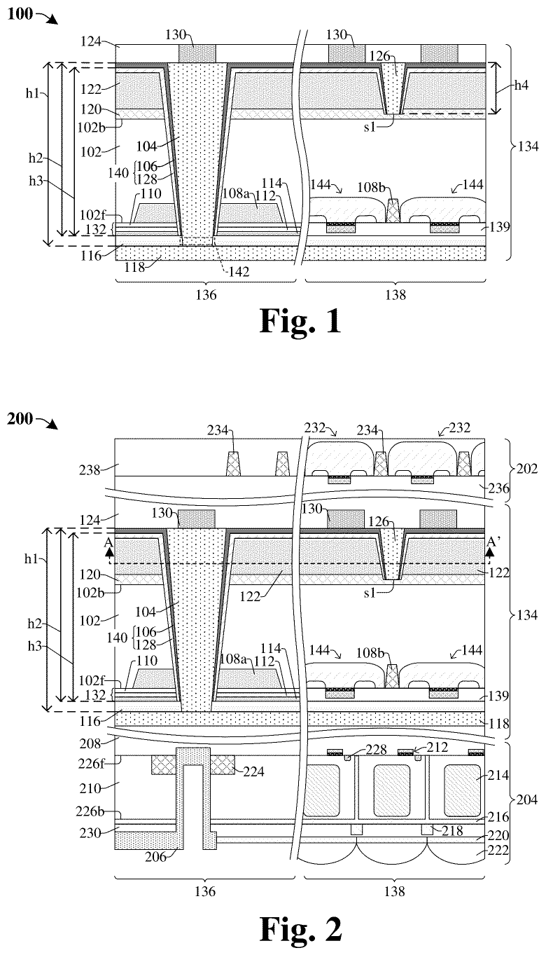

FIG. 1 illustrates a cross-sectional view 100 of some embodiments of a semiconductor device comprising an active through substrate via (TSV) and a dummy via.

Cross-sectional view 100 shows a device chip 134 with a device substrate 102. In some embodiments, the device chip 134 is any chip with an interconnect structure that electrically couples to another chip. The device substrate 102 has a front-side surface 102f opposite a back-side surface 102b. The device substrate 102 may be or comprise a semiconductor body (e.g., monocrystalline silicon, CMOS bulk, silicon-germanium, etc.) and has a first doping type (e.g., p-type). A plurality of dielectric layers 132 are disposed on the front-side surface 102f of the device substrate 102. The plurality of dielectric layers 132 can include a first dielectric layer 110 disposed on the front-side surface 102f, a second dielectric layer 112 disposed on the first dielectric layer 110, and a third dielectric layer 114 disposed on the second dielectric layer. In some embodiments, the first dielectric layer 110 is a blocking layer or a resist protection oxide that can be or comprise a dielectric, a low-k dielectric, or an oxide (e.g., silicon dioxide). In some embodiments, the second dielectric layer 112 is a contact etch stop layer and may be or comprise a dielectric, a low-k dielectric, or a nitride (e.g., silicon nitride). In some embodiments, the third dielectric layer 114 is a dielectric fill layer and can be or comprise an oxide or other dielectric material.

An inter-layer dielectric (ILD) layer 116 is disposed on the plurality of dielectric layers 132. In some embodiments, the ILD layer 116 may be or comprise a nitride, a carbide, an oxide, a low-k dielectric, or the like. A metal layer 118 is disposed on the ILD layer 116. The metal layer 118 may be or comprise copper, tungsten, aluminum, or the like. In some embodiments, the metal layer 118 comprises a wire or other interconnect device disposed within a dielectric (not shown).

A dielectric film 120 is disposed on the back-side surface 102b of the device substrate 102. The dielectric film 120 may be or comprise an oxide such as silicon dioxide, a low-k dielectric material, or the like. A lower dielectric layer 122 is disposed on the dielectric film 120 and an upper dielectric layer 124 is disposed over the lower dielectric layer 122. The upper dielectric layer 124 includes a plurality of wires 130. The lower dielectric layer 122 and the upper dielectric layer 124 can be or comprise a nitride, a carbide, an oxide, a low-k dielectric, or the like.

The device chip 134 has a peripheral region 136 laterally separated from a device region 138, where the peripheral region 136 is at the perimeter of the device chip 134 and the device region 138 is laterally surrounded by the peripheral region 136. A plurality of shallow-trench isolation (STI) structures 108a, 108b are disposed within the device substrate 102 extending from the front-side surface 102f in the peripheral region 136 and the device region 138. The plurality of STI structures 108a, 108b can be or comprise silicon dioxide, silicon nitride, silicon carbide, or the like.

An active TSV 104 is disposed within the peripheral region 136 and extends from the upper dielectric layer 124, through the lower dielectric layer 122, the dielectric film 120, the device substrate 102, a STI structure 108a of the plurality of STI structures 108a, 108b, the plurality of dielectric layers 132, and the ILD layer to contact the metal layer 118. The active TSV 104 has a first height h1 from a bottom surface of the upper dielectric layer 124 to a top surface of the metal layer 118. Furthermore, one of the plurality of wires 130 is disposed along a top surface of the active TSV 104. In some embodiments, the active TSV 104 can be or comprise one or more of copper, tungsten, aluminum, or another suitable metal.

A liner structure 140 is disposed along a top surface of the lower dielectric layer 122 thereby separating the upper dielectric layer 124 from the lower dielectric layer 122. The liner structure 140 extends along outer sidewalls of the active TSV 104 separating the active TSV 104 from the lower dielectric layer 122, the dielectric film 120, the device substrate 102, the STI structure 108a, and the plurality of dielectric layers 132. The liner structure 140 has a top surface disposed along the bottom surface of the upper dielectric layer 124 and a bottom surface disposed along a top surface of the ILD layer 116. As such, the liner structure 140 is not disposed along a bottom portion 142 of the active TSV 104 within the ILD layer 116. Thus, outer sidewalls of the bottom portion 142 of the active TSV 104 disposed within the ILD layer 116 contact the ILD layer 116. In some embodiments, the liner structure 140 provides electrical isolation and a diffusion barrier between the active TSV 104 and one or more of the lower dielectric layer 122, the dielectric film 120, or the device substrate 102.

In some embodiments, the liner structure 140 includes a first dielectric liner 128 and a second dielectric liner 106. In some embodiments, the first and second dielectric liners 128, 106 comprise the same material. In other embodiments, the first and second dielectric liners 128, 106 comprise different materials where the first dielectric liner 128 can be or comprise a nitride such as silicon nitride, a high-k dielectric comprising a nitride, or other nitrides, and the second dielectric liner 106 can be or comprise an oxide such as silicon dioxide, a high-k dielectric comprising an oxide, or other oxides. In some embodiments, the first and second dielectric liners 128, 106 comprise different materials with different etch rates, for example, where a material of the first dielectric liner 128 has a faster etch rate than a material of the second dielectric liner 106. The first dielectric liner 128 is disposed along the top surface of the lower dielectric layer 122 and the second dielectric liner 106 is disposed on a top surface of the first dielectric liner 128, and separates the first dielectric liner 128 from the upper dielectric layer 124. The second dielectric liner 106 extends from the upper dielectric layer 124 along outer sidewalls of the active TSV 104 to the top surface of the ILD layer 116 and has a second height h2 that is less than the first height h1 of the active TSV 104. Furthermore, the second dielectric liner 106 separates the active TSV 104 from the first dielectric liner 128.

The first dielectric liner 128 extends from a lower surface of the second dielectric liner 106 above the lower dielectric layer 122 to the top surface of the ILD layer 116 and has a third height h3 that is less than the first height h1 of the active TSV 104 and less than the second height h2 of the second dielectric liner 106. Furthermore, the first dielectric liner 128 separates the second dielectric liner 106 from the device substrate 102.

A dummy via 126 is laterally offset from the active TSV 104, where the dummy via 126 is disposed within the device region 138. The dummy via 126 is disposed within the lower dielectric layer 122 where the dummy via 126 extends from the bottom surface of the upper dielectric layer 124. As such, a top surface of the dummy via 126 is substantially co-planar with the top surface of the active TSV 104. That is, the active TSV 104 and the dummy via 126 extend from a common surface defined by the bottom surface of the upper dielectric layer 124. A bottom surface s1 of the dummy via 126 is separated from the front-side surface of the device substrate 102. In some embodiments, the bottom surface s1 of the dummy via contacts the dielectric film 120 where the bottom surface s1 of the dummy via 126 fully contacts the dielectric film 120. That is, the bottom surface s1 of the dummy via 126 contacts the dielectric film 120 across an entirety of the bottom surface s1 of the dummy via 126. In this embodiment, the bottom surface s1 of the dummy via 126 is disposed above the back-side surface 102b of the device substrate 102. In some embodiments, the dummy via 126 can be or comprises one or more of copper, tungsten, aluminum, or another suitable metal. In this embodiment, the bottom surface s1 fully contacts a dielectric, such as the dielectric film 120. In other embodiments, the bottom surface s1 fully contacts the lower dielectric layer 122 or the device substrate 102 (not shown). In some embodiments, the dummy via 126 is aligned over a STI structure 108b. In some embodiments, a top surface of the dummy via 126 fully contacts the upper dielectric layer 124.

The dummy via 126 has a fourth height h4 from a bottom surface of the upper dielectric layer 124 to the bottom surface s1 within the dielectric film 120. The fourth height h4 is less than the first height h1 of the active TSV 104. In some embodiments, the first height h1 of the active TSV 104 ranges from one to two times, from two to three times, or is more than three times that of the fourth height h4 of the dummy via 126. Furthermore, in some embodiments, a width of the active TSV 104 ranges from one to two times, from two to three times, or is more than three times that of a width of the dummy via 126.

The liner structure 140 is disposed along outer sidewalls of the dummy via 126 separating the dummy via 126 from the lower dielectric layer 122 and separating outer sidewalls of the dummy via 126 from the dielectric film 120. The first dielectric liner 128 is disposed between outer sidewalls of the dummy via 126 and the lower device dielectric, and separates outer sidewalls of the dummy via 126 from the dielectric film 120. The second dielectric liner 106 is disposed along sidewalls of the dummy via 126 where the second dielectric liner 106 is disposed along inner sidewalls of the first dielectric liner 128 and separates the dummy via 126 from the first dielectric liner 128. The second dielectric liner 106 extends from the top surface of the dummy via 126 to the bottom surface s1 of the dummy via 126 and has a vertical height that is the same as the fourth height h4 of the dummy via 126. The first dielectric liner 128 extends from a bottom surface of the second dielectric liner 106 disposed above the lower dielectric layer 122 to the bottom surface s1 of the dummy via 126 and has a vertical height that is less than the vertical height of the second dielectric liner 106. The liner structure 140 provides electrical isolation and a diffusion barrier between the dummy via 126 and the lower dielectric layer 122, and the dielectric film 120.

In some embodiments, a device dielectric layer 139 is disposed between the front-side surface 102f of the device substrate 102 and the ILD layer 116, where the device dielectric layer 139 is vertically aligned with the plurality of dielectric layers 132. A plurality of active devices 144 are disposed on the front-side surface 102f of the device substrate 102 under the dummy via 126, where gate electrodes of the plurality of active devices 144 are disposed within the device dielectric layer. The plurality of active devices 144 can be separated from one another by STI structures such as the STI structure 108b. The device dielectric layer 139 can be or comprise a nitride, a carbide, an oxide, a low-k dielectric, or the like. In some embodiments, the plurality of active devices 144 can provide configuration functions for a semiconductor device, such as reset transistors for an image sensor.

In some embodiments, the active TSV 104 is coupled to an active device, for example, one of the plurality of active devices 144 and/or an active device of another chip (not pictured). As the dummy via 126 is electrically isolated from other active devices, such as the plurality of active devices 144 or other active devices, the bottom surface s1 of the dummy via 126 is disconnected from conductive interconnects or a metal structure (e.g., wires, vias, etc.)

By disposing the dummy via 126 within the lower dielectric layer 122, the dummy via 126 provides structural support and rigidity to device chip 134 to reduce or eliminate the risk of inter-chip or inter-layer delamination or deformation caused by stresses within the device region 138 of the multi-stack chip cause by mechanical stresses including thermal expansion. Furthermore, the active TSV 104 provides structural support at the peripheral region 136 of the device chip 134.

FIG. 2 illustrates a cross-sectional view 200 of some embodiments of a stacked image sensor having an imaging chip 204, a device chip 134, and a logic chip 202.

Some embodiments of an imaging chip 204 bonded to the bottom side of the device chip 134 are shown. Some embodiments of a logic chip 202 bonded to the top side of the device chip 134 are shown. The imaging chip 204 includes a dielectric interconnect structure 208 disposed under the device chip 134 and an imaging substrate 210 disposed on a bottom surface of the dielectric interconnect structure 208.

The device region 138 of the imaging chip 204 includes a plurality of transfer transistors 212 disposed within the dielectric interconnect structure 208 on a front-side surface 226f of the imaging substrate 210. The imaging substrate 210 may be or comprise a semiconductor body (e.g., monocrystalline silicon, CMOS bulk, silicon-germanium, etc.) and has a first doping type (e.g., p-type). A plurality of floating diffusion nodes 228 are disposed within the imaging substrate 210 and on the front-side surface 226f of the imaging substrate 210 and are coupled to the plurality of transfer transistors 212. A plurality of photodetectors 214 are disposed under the plurality of floating diffusion nodes 228 within the imaging substrate 210 where the plurality of photodetectors 214 are separated from one another by an isolation structure 216. The isolation structure 216 is disposed along a back-side surface 226b of the imaging substrate 210 and extends through the imaging substrate 210 between the plurality of photodetectors 214 forming a grid structure. A lower dielectric layer 230 is disposed on a bottom surface of the isolation structure 216. A grid structure 218 is disposed within the isolation structure 216 aligned between the plurality of photodetectors 214. A plurality of light filters 220 are disposed on the lower dielectric layer 230. A plurality of micro-lenses 222 are disposed on the light filters 220.

As such, the device region 138 of the imaging chip 204 includes imaging devices that are aligned under the dummy via 126. The plurality of micro-lenses 222 are configured to direct incident light towards the plurality of photodetectors 214. The plurality of light filters 220 each comprise a material configured to pass a first range of wavelengths while blocking a second range of wavelengths to the each of the plurality of photodetectors 214. The grid structure 218 and the isolation structure 216 provide isolation of photons and electrons between the plurality of photodetectors 214. The photodetectors 214 are configured to absorb incident light (e.g., photons) received through the micro-lenses 222 and generate respective electrical signals corresponding to the incident light. For example, the plurality of photodetectors 214 may generate electron-hole pairs from the incident light. The plurality of transfer transistors 212 can selectively form a conductive channel in the imaging substrate 210 between the plurality of floating diffusion nodes 228 and the plurality of photodetectors 214 to transfer accumulated charge in the plurality of photodetectors 214 to the plurality of floating diffusion nodes 228. The plurality of transfer transistors 212 are configured to conduct and transfer the accumulated charge from the plurality of floating diffusion nodes 228.

The peripheral region 136 of the imaging chip 204 includes a bond pad 206 that is laterally offset from the plurality of photodetectors 214. The bond pad 206 extends through the lower dielectric layer 230, through the isolation structure 216, through the imaging substrate 210, and into the dielectric interconnect structure 208. The bond pad 206 is configured to provide electrical connection to devices (e.g., the plurality of transfer transistors 212, the plurality of active devices 144, or active devices disposed within the logic chip 202) of the stacked image sensor and/or another IC device (not shown). An isolation structure 224 is disposed within the imaging substrate 210 and may be configured as a STI structure and may, for example, be or comprise silicon dioxide, silicon nitride, silicon carbide, or the like. The isolation structure 224 is disposed on the front-side surface 226f of the imaging substrate 210 and extends along sidewalls of the bond pad 206 and is configured to increase electrical isolation between the bond pad 206 and other devices (e.g., the plurality of photodetectors 214, the plurality of floating diffusion nodes 228, the plurality of transfer transistors 212) disposed on and/or within the imaging substrate 210. Furthermore, the bond pad is aligned under the active TSV 104.

The logic chip 202 comprises a logic dielectric layer 236 disposed over the upper dielectric layer 124 of the device chip 134. The logic chip 202 also comprises a logic substrate 238 disposed on the logic dielectric layer 236. The logic dielectric layer 236 may be or comprise a nitride, a carbide, an oxide, a low-k dielectric, or the like. The logic substrate 238 may be or comprise a semiconductor body (e.g., monocrystalline silicon, CMOS bulk, silicon-germanium, etc.) and has a first doping type (e.g., p-type).

A plurality of logic devices 232 are disposed within the logic substrate 238 within the device region 138 aligned over the dummy via 126. In some embodiments, the plurality of logic devices 232 can include transistors, logic gates, or other devices configured as an application-specific integrated circuit (ASIC) which can facilitate downstream signal processing of the charge accumulated by the plurality of photodetectors 214 that is read out by the device chip 134. The plurality of logic devices 232 are separated from one another by a plurality of STI structures 234. In some embodiments, the plurality of STI structures 234 are disposed within the logic substrate 238 aligned over the active TSV 104.

The active TSV 104 and the dummy via 126 of FIG. 2 can provide structural support to the device chip 134 that prevents delamination or deformation of layers of the device chip 134 or bonding interface between the device chip 134 and the logic chip 202.

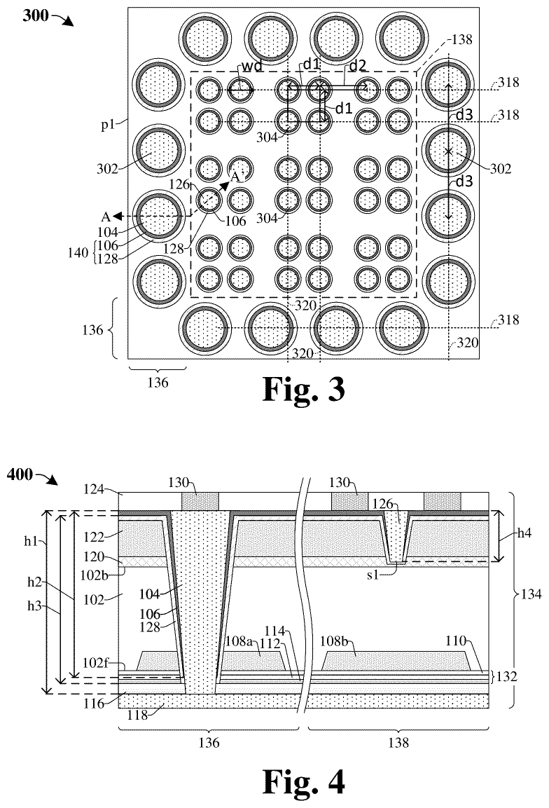

FIG. 3 illustrates a top view 300 of some embodiments of the stacked image sensor of FIG. 2 taken along the line A-A′ of FIG. 2. It is appreciated that for ease of illustration, the lower dielectric layer (122 of FIG. 2) is omitted from the top view 300 of FIG. 2.

As shown in FIG. 2, the dummy via 126 is disposed within the device region 138 and the active TSV 104 is disposed within the peripheral region 136, where the dummy via 126 and the active TSV 104 are round in shape. The dummy via 126 and the active TSV 104 are encompassed by the liner structure 140. The liner structure 140 can include the second dielectric liner 106 disposed along outer edges of the dummy via 126 and the active TSV 104. The liner structure 140 can further include the first dielectric liner 128 that is disposed along outer edges of the second dielectric liner 106.

The device region 138 includes a plurality of dummy vias 304 that includes the dummy via 126. The peripheral region 136 includes a plurality of active TSVs 302 that includes the active TSV 104. The plurality of active TSVs 302 are disposed about an outermost perimeter p1 of the device chip (134 of FIG. 2). As such, the plurality of active TSVs 302 are disposed laterally surrounding the device region 138. In some embodiments, the number of dummy vias and the height/width of the dummy vias of the plurality of dummy vias 304 can be selected based on design constraints and structural criteria to eliminate delamination and deformation of layers and chips within the multi-stack chip.

In the example of FIG. 3, the dummy vias 304 are arranged so centers of the dummy vias 304 lie along horizontal lines 318 and vertical lines 320 that establish a series of columns and rows. Some of the horizontal lines and vertical are equally spaced from one another by a first distance d1 to establish clusters of dummy vias (e.g., centers of the dummy vias define a square when viewed from above). The first and second distances d1, d2 are also less than a diametric width wd of the dummy vias. Nearest neighboring clusters are then spaced apart from one another by a second distance d2, which is greater than the first distance. In other examples, however, the dummy vias could form linear clusters, triangular clusters, rectangular clusters, other polygonal clusters, or could be randomly or pseudo-randomly spaced to be separated by different/varying distances over the device region 138. Further, the plurality of active TSVs 302 FIG. 3 form a structure that encloses or fully surrounds the device region 138. The nearest neighboring plurality of active TSVs in FIG. 3 have centers that are spaced apart at a third distance that is greater than the first distance, and which can be greater or less than the second distance. Although FIG. 3 shows an example where the plurality of active TSVs 302 are a single row thick, in other cases multiple rows of active TSVs can concentrically surround the device region 138.

FIG. 4 illustrates a cross-sectional view 400 of some embodiments of a semiconductor device comprising an active TSV 104 and a dummy via 126 corresponding to some other embodiments of the semiconductor device of FIG. 1. FIG. 4 shows alternative embodiments of the liner structure 140.

FIG. 4 shows the plurality of dielectric layers 132 extending into the device region 138 where the dummy via 126 is disposed over the plurality of dielectric layers 132. A STI structure 108b is disposed within the device region on the front-side surface 102f aligned under the dummy via 126. The second dielectric liner 106 extends along outer sidewalls of the active TSV 104 from the top surface of the active TSV 104 to a bottom surface of the second dielectric liner 106 disposed above a bottom surface of the first dielectric liner 128. In some embodiments, the bottom surface of the second dielectric liner 106 is horizontally aligned with the second dielectric layer 112 (shown) or the first dielectric layer 110 (not shown), or the third dielectric layer 114 (not shown) of the plurality of dielectric layers 132. Between a bottom surface of the second dielectric liner 106 and a bottom surface of the active TSV 104, the first dielectric liner 128 is disposed along outer sidewalls of the active TSV 104. In this embodiment, the second height h2 of the second dielectric liner 106 is less than the third height h3 of the first dielectric liner 128.

The first dielectric liner 128 extends below the dummy via 126 and the bottom surface s1 of the dummy via 126 fully contacts the first dielectric liner 128. That is, the bottom surface s1 of the dummy via 126 contacts the first dielectric liner 128 across an entirety of the bottom surface s1. The second dielectric liner 106 extends along outer sidewalls of the dummy via 126 from the top surface of the dummy via 126 to a top surface of the dielectric film 120 disposed above the bottom surface of the dummy via 126 with a vertical height that is less than the fourth height h4 of the dummy via 126. As such, the first dielectric liner 128 is disposed along outer sidewalls of the dummy via 126 between the bottom surface of the second dielectric liner 106 and the bottom surface s1 of the dummy via 126. The first dielectric liner 128 extends from a bottom surface of the second dielectric liner 106 disposed above the lower dielectric layer 122 to under the bottom surface s1 and has a vertical height that is greater than the vertical height of the second dielectric liner 106 and less than the fourth height h4 of the dummy via 126.

Aspects of the first dielectric liner 128 and the second dielectric liner 106 as they relate to the active TSV 104 and the dummy via 126 discussed in accordance with FIG. 4 can correspond to formation techniques to realize critical dimensions for the active TSV 104 and dummy via 126.

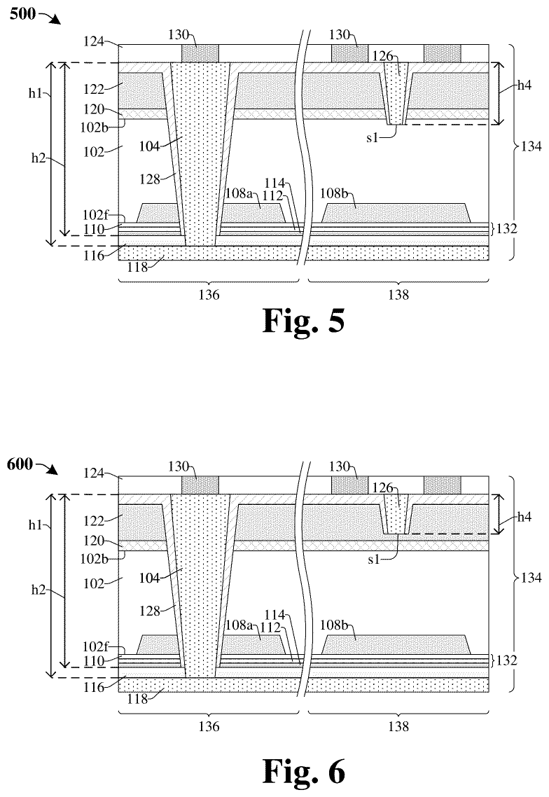

FIG. 5 illustrates a cross-sectional view 500 of some embodiments of a semiconductor device comprising an active TSV 104 and a dummy via 126 corresponding to some other embodiments of the semiconductor device of FIG. 1. FIG. 4 shows alternative embodiments of the liner structure 140 and the dummy via 126.

FIG. 5 shows the liner structure 140 as a single dielectric structure. The liner structure 140 can be or comprise a nitride, an oxide, a high-k dielectric, or other suitable dielectric. The liner structure 140 extends along outer sidewalls of the active TSV 104 from a top surface of the active TSV 104 to a top surface of the ILD layer 116. The dummy via 126 extends from the upper dielectric layer 124, through the lower dielectric layer 122 and the dielectric film 120 where the bottom surface s1 of the dummy via 126 is disposed within the device substrate 102 above the front-side surface 102f of the device substrate 102. The liner structure 140 extends from the top surface of the dummy via 126 to the bottom surface s1 of the dummy via 126. The bottom surface of the dummy via 126 fully contacts the device substrate 102.

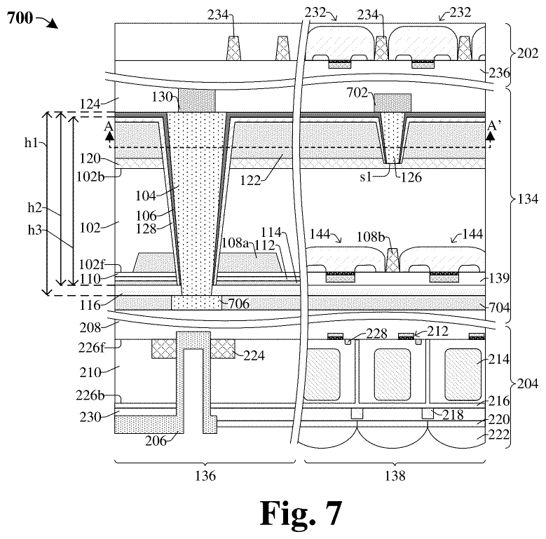

FIG. 6 illustrates a cross-sectional view 600 of some embodiments of a semiconductor device comprising an active TSV 104 and a dummy via 126 corresponding to some other embodiments of the semiconductor device of FIG. 5. FIG. 6 shows alternative embodiments of the liner structure 140 and the dummy via 126.

FIG. 6 shows the dummy via 126 extending from the bottom surface of the upper dielectric layer 124 to a bottom surface s1 of the dummy via 126 disposed above a bottom surface of the lower dielectric layer 122. The liner structure 140 extends along sidewalls of the dummy via 126. The bottom surface s1 of the dummy via 126 fully contacts the lower dielectric layer 122.

FIGS. 1, 4, 5, and 6 show various aspects of the fourth height h4 of the dummy via 126, and the bottom surface s1 of the dummy via 126 contacting the liner structure 140, lower dielectric layer 122, dielectric film 120, or device substrate 102. Furthermore, various aspects of the liner structure 140 related to the active TSV 104 are shown. These aspects are variations to achieve desired critical dimensions of the dummy via 126 that add structural support to the device chip 134 to prevent deformation or delamination of layers or chips of a stacked chip. It is understood that aspects of one figure can apply to another figure. For example, the liner structure 140 shown as a single dielectric layer (FIGS. 5 and 6) can apply to FIG. 1. The liner structure 140 comprising the first dielectric liner 128 and the second dielectric liner 106 of FIGS. 1 and 4 can apply to FIGS. 5 and 6. The height of the dummy via 126 of FIGS. 5 and 6 can apply to FIGS. 1 and 4 or vice versa.

FIG. 7 illustrates a cross sectional view 700 of some embodiments of a stacked image sensor corresponding to some other embodiments of the stacked image sensor of FIG. 2.

FIG. 7 shows a bond dielectric layer 704 disposed on a bottom surface of the ILD layer 116 and the device dielectric layer 139. The bond dielectric layer 704 may be or comprise a nitride, a carbide, an oxide, a low-k dielectric, or the like. A wire 706 is disposed within the bond dielectric layer 704 and contacts the bottom surface of the active TSV 104. The active TSV 104 can connect to active devices (e.g., devices in the logic chip 202, device chip 134, or imaging chip 204) through one or more of the wire 706 and/or a wire of the plurality of wires 130 disposed on the top surface of the active TSV 104.

A wire 702 is disposed on the top surface of the dummy via 126 disposed within the upper dielectric layer 124. The wire 702 can provide additional structural support to the device chip 134 that in tandem with the dummy via 126 prevents delamination or deformation of layers and chips of the stacked image sensor. The wire 702 is electrically isolated from active devices (e.g., devices in the logic chip 202, device chip 134, or imaging chip 204). It is appreciated that FIGS. 1, 2, and 4-6 can include the wire 702 or the wire 706 of FIG. 7.

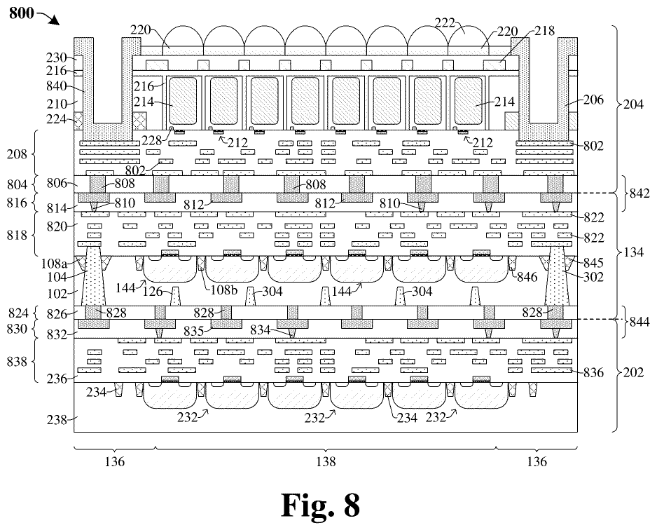

FIG. 8 illustrates a cross sectional view 800 of some embodiments of a stacked image sensor according to other embodiments of the stacked image sensor of FIGS. 2 and 7. FIG. 8 illustrates additional embodiments of the imaging chip 204, the device chip 134, and the logic chip 202.

The imaging chip 204 comprises features described in accordance with the imaging chip 204 of FIG. 2. FIG. 8 shows a bond pad 206 and a bond pad 840 in the peripheral region 136 of the imaging chip 204 where the device region 138 between the bond pads 206, 840 is comprises photodetectors 214 and associated circuitry in the imaging substrate 210. The plurality of floating diffusion nodes 228 are disposed under the plurality of photodetectors 214 within the imaging substrate 210. The dielectric interconnect structure 208 is disposed under the imaging substrate 210. The plurality of transfer transistors 212 are disposed within the dielectric interconnect structure 208. A plurality of conductive wires 802 are disposed within the imaging substrate 210. The plurality of conductive wires 802 can electrically couple one or more of the transfer transistors 212 or bond pads 206, 840 to one another or to other active devices within the stacked image sensor. An imaging bond structure 804 is disposed on the dielectric interconnect structure 208. The imaging bond structure 804 comprises an image bonding dielectric 806 and a plurality of imaging bond pads 808.

The device chip 134 has a first device bond structure 816 comprising a first device bonding dielectric 814 and a plurality of device bonding contacts 810 and a plurality of device bonding pads 812. The imaging bond structure 804 meets the first device bond structure 816 at a bonding interface thereby defining a bonded structure 842 that connects the imaging chip 204 to the device chip 134. The device chip 134 further comprises a device interconnect structure 818 disposed on the bottom side of the first device bond structure 816, a device substrate 102 disposed on the bottom side of the device interconnect structure 818, and a second device bond structure 824 disposed on a bottom side of the device substrate 102. The device interconnect structure 818 comprises an interconnect dielectric structure 820 having a plurality of wires and interconnect structures 822.

The device dielectric 102 has a plurality of active TSVs 302, 104 that are disposed in the peripheral region of the device chip 134. The active TSVs 302, 104 extend from a bottom surface of the device substrate 102, through respective STI structures 108a, 845. The active TSVs 302, 104 extend into the interconnect dielectric structure 820 and each electrically couple to one or more of the plurality of wires and interconnect structures 822. Between the active TSVs 302, 104 and in the device region 138, a plurality of dummy vias 126, 304 are disposed within the device substrate 102. The plurality of dummy vias 126, 304 are separated from a plurality of active devices 144 and a plurality of STI structures 108b, 846 by the device substrate 102. Furthermore, the plurality of dummy vias 126, 304 are electrically disconnected from active devices of the stacked image sensor. The second device bond structure 824 comprises a second device bonding dielectric 826 with a plurality of device bonding contacts 828. The active TSVs 302, 104 are electrically coupled to one or more of the device bonding contacts 828.

The logic chip 202 comprises a logic bond structure 830, a logic interconnect structure 838 disposed on the logic bond structure 830, and a logic substrate 238 disposed on the logic interconnect structure 838. The logic bond structure 830 comprises a logic bond dielectric 832 comprising device bonding contacts 834 and device bonding pads 835. The second device bond structure 824 meets the logic bond structure 830 at a bonding interface thereby defining a bonded structure 844 that connects the logic chip 202 to the device chip 134. The logic chip 202 further comprises a logic interconnect structure 838 disposed on the logic bond structure 830, and a logic substrate 238 disposed on the logic bond structure 830. The logic interconnect structure 838 comprises a logic dielectric layer 236 having a plurality of conductive wires 836. The logic substrate 238 has a plurality of logic devices 232 separated from one another by a plurality of STI structures 234. The plurality of logic devices 232 are disposed within the device region 138 of the logic chip 202.

The plurality of dummy vias 126, 304 are electrically insulated and disconnected from active devices. The plurality of dummy vias 126, 304 provide structural support to prevent delamination or deformation caused by stress between layers or chips of the stacked image sensor. For example, the plurality of dummy vias 126, 304 prevents delamination of the device substrate 102 from the second device bonding dielectric 826, or prevents delamination of the device chip 134 from the logic chip 202.

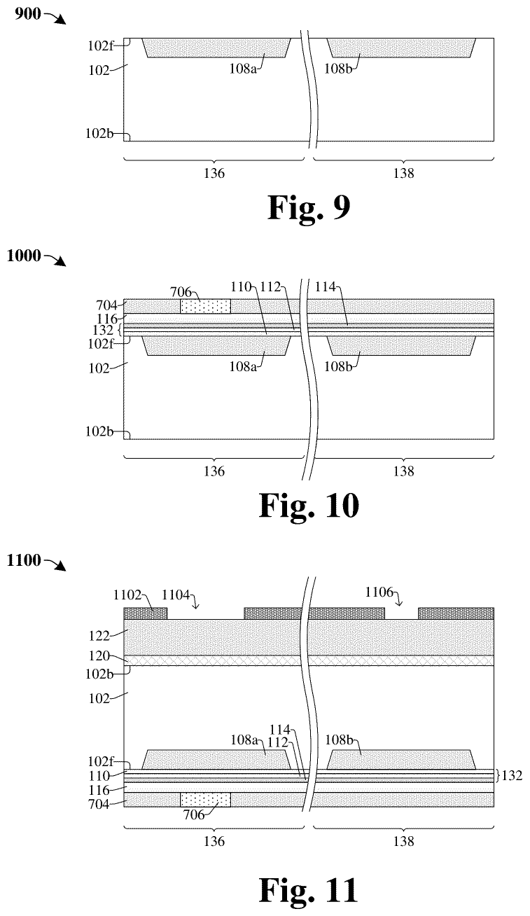

FIGS. 9-18 illustrate various views 900-1800 of some embodiments of a method for forming a stacked image sensor comprising a dummy via in a device region and an active TSV in a peripheral region. Although the various views 900-1800 shown in FIGS. 9-18 are described with reference to the method, it will be appreciated that the structures shown in FIGS. 9-18 are not limited to the method but rather may stand alone separate of the method. Furthermore, although FIGS. 9-18 are described as a series of acts, it will be appreciated that these acts are not limited in that the order of the acts can be altered in other embodiments, and the methods disclosed are also applicable to other structures. In other embodiments, some acts that are illustrated and/or described may be omitted in whole or in part.

As shown in cross-sectional view 900 of FIG. 9, a plurality of STI structures 108a, 108b are formed within a device substrate 102 disposed along a front-side surface 102f of the device substrate 102. The STI structure 108a is formed within a peripheral region 136 of the device substrate 102, and the STI structure 108b is formed within a device region 138 of the device substrate 102. The peripheral region 136 extends around an outer perimeter (not shown) of the device substrate 102) where the peripheral region 136 surrounds the device region 138. In some embodiments, the device substrate 102 may be or comprise a bulk silicon substrate, monocrystalline silicon, epitaxial silicon, silicon germanium (SiGe), or another suitable semiconductor material and/or comprises a first doping type (e.g., p-type). In some embodiments, the plurality of STI structures 108a, 108b may be or comprise silicon dioxide, silicon nitride, silicon carbide, a low-k dielectric, or the like.

In some embodiments, a patterned photoresist (not shown) is formed along the front-side surface 102f. An etching process (not shown) is performed through the patterned photoresist to form openings (not shown) within the peripheral region 136 and the device region 138 of the device substrate 102, and the patterned photoresist removed. The openings are filled with a dielectric layer (not shown), and the dielectric material can be deposited along the front-side surface 102f. A removal process (not shown) is applied to the dielectric layer such as a chemical mechanical planarization (CMP) process to remove the dielectric layer from the front-side surface 102f and form the plurality of STI structures 108a, 108b.

As shown in cross-sectional view 1000 of FIG. 10, a plurality of dielectric layers 132, an ILD layer 116, and a bond dielectric layer 704 are formed over the front-side surface 102f of the device substrate 102. The plurality of dielectric layers 132 are formed along the front-side surface 102f of the device substrate 102 and along exposed surfaces of the plurality of STI structures 108a, 108b. The plurality of dielectric layers 132 include a first dielectric layer 110 formed on the front-side surface 102f, a second dielectric layer 112 formed on the first dielectric layer 110, and a third dielectric layer 114 formed on the second dielectric layer 112. The plurality of dielectric layers 132 can be formed, for example, by a series of deposition processes such as chemical vapor deposition (CVD), plasma enhanced CVD (PECVD), atomic layer deposition (ALD), thermal oxidation, or the like. In some embodiments, the first dielectric layer 110 is a blocking layer or a resist protection oxide that can be or comprise a dielectric, a low-k dielectric, or an oxide (e.g., silicon dioxide). In some embodiments, the second dielectric layer 112 is a contact etch stop layer and may be or comprise a dielectric, a low-k dielectric, or a nitride (e.g., silicon nitride). In some embodiments, the third dielectric layer 114 is a dielectric fill layer and can be or comprise an oxide or other dielectric material.

The ILD layer 116 is formed on the third dielectric layer 114 and can be formed according to a deposition process such as CVD, PECVD, ALD, or the like. The ILD layer 116 layer may be or comprise a nitride, a carbide, an oxide, a low-k dielectric, or the like. The bond dielectric layer 704 is formed on the ILD layer 116 and may be formed according to a deposition process such as CVD, PECVD, ALD, or the like. The bond dielectric layer 704 may be or comprise a nitride, a carbide, an oxide, a low-k dielectric, or the like. A wire 706 is formed within the bond dielectric layer 704 aligned with the peripheral region 136. The wire 706 can be formed according to an etch (not shown) through a patterned photoresist (not shown), deposition process of a metal (not shown), and subsequent removal process like planarization (not shown). The wire 706 may be or comprise copper, tungsten, aluminum, or another metal.

As illustrated in cross-sectional view 1100 of FIG. 1100, the structure of FIG. 10 is rotated 180 degrees for further processing steps on the back-side surface 102b of the device substrate 102 that is opposite the front-side surface 102f. A dielectric film 120 is formed along the front-side surface 102f. The dielectric film 120 may be formed according to a deposition process such as CVD, PECVD, ALD, or the like. The dielectric film 120 may be or comprise an oxide such as silicon dioxide, a low-k dielectric material, or the like. A lower dielectric layer 122 is formed on a top surface of the dielectric film 120 according to a deposition process such as CVD, PECVD, ALD, or the like. The lower dielectric layer 122 may be or comprise a nitride, a carbide, an oxide, a low-k dielectric, or the like. A patterned photoresist 1102 is formed on the lower dielectric layer 122. The patterned photoresist 1102 can be patterned according to a lithography process (not shown) with a TSV opening 1104 formed over the lower dielectric layer 122 in the peripheral region 136 aligned over the wire 706. The patterned photoresist 1102 is formed with a dummy via opening 1106 over the lower dielectric layer 122 in the device region 138. The TSV opening 1104 is larger than the dummy via opening 1106. In some embodiments, the TSV opening 1104 has a width that ranges from one to two times, from two to three times, or is more than three times of a width of the dummy via opening 1106.

As illustrated in cross-sectional view 1200 of FIG. 1200, a first etch 1202 is performed through the TSV opening 1104 and dummy via opening 1106 of the patterned photoresist 1102. In some embodiments, the first etch 1202 may be a dry etch, a reactive ion etch (RIE), a plasma etch, a wet etch, or other etching process. The first etch 1202 forms an active TSV opening 1204 in the peripheral region 136 aligned under the TSV opening 1104. The active TSV opening 1204 extends through the lower dielectric layer 122, the dielectric film 120, the device substrate 102, the STI structure 108a, and the plurality of dielectric layers 132. The active TSV opening 1204 exposes a top surface of the ILD layer 116 aligned over the wire 706.

The first etch 1202 also forms a dummy via opening 1206 in the device region 138 aligned under the dummy via opening 1106. The dummy via opening 1206 extends through the lower dielectric layer 122 and extends into the dielectric film 120 thereby exposing the dielectric film 120, where a bottom surface of the dummy via opening 1206 is above a bottom surface of the dielectric film 120. In other embodiments (not shown), the dummy via opening 1206 extends into the lower dielectric layer 122 with a bottom surface that is above a bottom surface of the lower dielectric layer 122. In other embodiments (not shown), the dummy via opening 1206 extends through both the lower dielectric layer 122 and the dielectric film 120, and into the device substrate 102, where the bottom surface of the dummy via opening 1206 is above the front-side surface 102f of the device substrate 102. The dummy via opening 1206 is formed with critical dimensions (e.g., height and width) that is less than critical dimensions of the active TSV opening 1204 because the dummy via opening 1106 within the patterned photoresist 1102 is smaller than the TSV opening 1104 within the patterned photoresist.

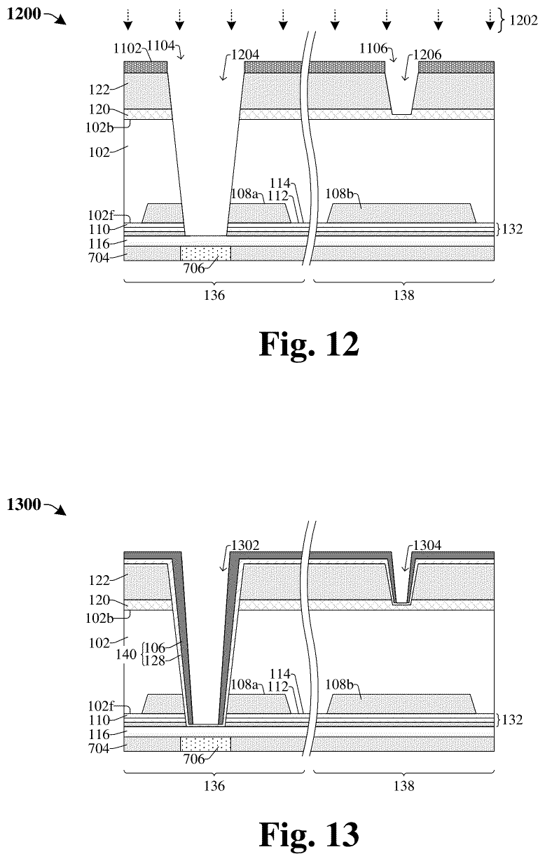

As illustrated in cross-sectional view 1300 of FIG. 1300, a liner structure 140 is formed over the lower dielectric layer 122 and within the active TSV opening 1204 and dummy via opening 1206 (of FIG. 12). The liner structure 140 is formed with a first dielectric liner 128 and a second dielectric liner 106. The first dielectric liner is deposited along a top surface of the lower dielectric layer 122 and exposed sidewalls of the active TSV opening 1204 and dummy via opening 1206 (of FIG. 12). That is, the first dielectric liner 128 is deposited along exposed surfaces of the lower dielectric layer 122, the dielectric film 120, the device substrate 102, the STI structure 108a, the plurality of dielectric layers 132, and the top surface of the ILD layer 116. The first dielectric liner 128 may be deposited according to a CVD process, PECVD process, ALD process, or some other suitable deposition or growth process.

The second dielectric liner 106 is formed over a top surface of the first dielectric liner 128 and along sidewalls of the first dielectric liner. In some the second dielectric liner 106 is not formed on bottom surfaces of the first dielectric liner 128 within the peripheral region 136 or the device region 138. In other embodiments, the second dielectric liner 106 is formed on bottom surfaces (now shown) of the first dielectric liner 128. The second dielectric liner 106 may be deposited according to a CVD process, PECVD process, ALD process, or some other suitable deposition or growth process. In some embodiments, the second dielectric liner 106 is deposited with a thickness that is greater than a thickness of the first dielectric liner 128.

In some embodiments, the first and second dielectric liners 128, 106 comprise the same material. In other embodiments, the first and second dielectric liners 128, 106 comprise different materials where the first dielectric liner 128 can be or comprise a nitride such as silicon nitride, a high-k dielectric comprising a nitride, or other nitrides, and the second dielectric liner 106 can be or comprise an oxide such as silicon dioxide, a high-k dielectric comprising an oxide, or other oxides. In some embodiments, the first dielectric liner 128 is formed from a material with a faster etch rate relative to an etch rate of the second dielectric liner 106. After forming the liner structure 140, an active TSV opening 1302 is defined within the peripheral region 136 defined by sidewalls of the second dielectric liner and a first exposed surface of the first dielectric liner 128 vertically aligned with the plurality of dielectric layers 132. Furthermore, after forming the liner structure 140, a dummy via opening 1304 is defined within the device region 138 defined by sidewalls of the second dielectric liner and a second exposed surface of the first dielectric liner 128 vertically aligned with the dielectric film 120. As such, the second exposed surface of the first dielectric liner 128 is above the first exposed surface of the first dielectric liner 128. It is appreciated that FIG. 13 can be modified to have a liner structure with a single material rather than the first and second dielectric liners 128, 106, for example, the liner structure 140 as shown in FIGS. 5-6.

As illustrated in cross-sectional view 1400 of FIG. 1400, a second etch 1402 is performed over the second dielectric liner 106 within the active TSV opening 1302 and the dummy via opening 1304. In some embodiments, the second etch 1402 may be a dry etch, a RIE, a plasma etch, a wet etch, or other etching process. The second etch 1402 thins the second dielectric liner 106 and etches through the first exposed surface (of FIG. 13) of the first dielectric liner 128. For example, a top surface of the second dielectric liner 106 is reduced in height by a reduction amount 1408. Furthermore, the portions of the second dielectric liner 106 that extend into the active TSV opening 1302 and dummy via opening 1304 are reduced in thickness. In the peripheral region 136, the second etch 1402 etches through the ILD layer 116 and exposes the wire 706. In the device region 138, the second etch 1402 etches through the second exposed surface (of FIG. 13) of the first dielectric liner 128 and exposes the dielectric film 120. As such, the active TSV opening 1302 is increased in size to the active TSV opening 1404 in the peripheral region 136 defined by sidewalls of the second dielectric liner 106, sidewalls of the ILD layer 116, and the top surface of the wire 706. The dummy via opening 1304 is increased in size to the dummy via opening 1406 in the device region 138 defined by sidewalls of the second dielectric liner 106 and the dielectric film 120. The active TSV opening 1404 is formed with a first height h1 extending from a top surface of the second dielectric liner 106 to the top surface of the wire 706. The second dielectric liner 106 is formed with a second height h2 extending from the top surface of the second dielectric liner 106 disposed above the lower dielectric layer 122 to the top surface of the ILD layer 116. The first dielectric liner 128 is formed with a third height h3 extending from the top surface of the first dielectric liner 128 disposed above the lower dielectric layer 122 to the top surface of the ILD layer 116. The dummy via opening 1406 is formed with a fourth height h4 extending from the top surface of the second dielectric liner 106 to the exposed surface of the dielectric film 120.

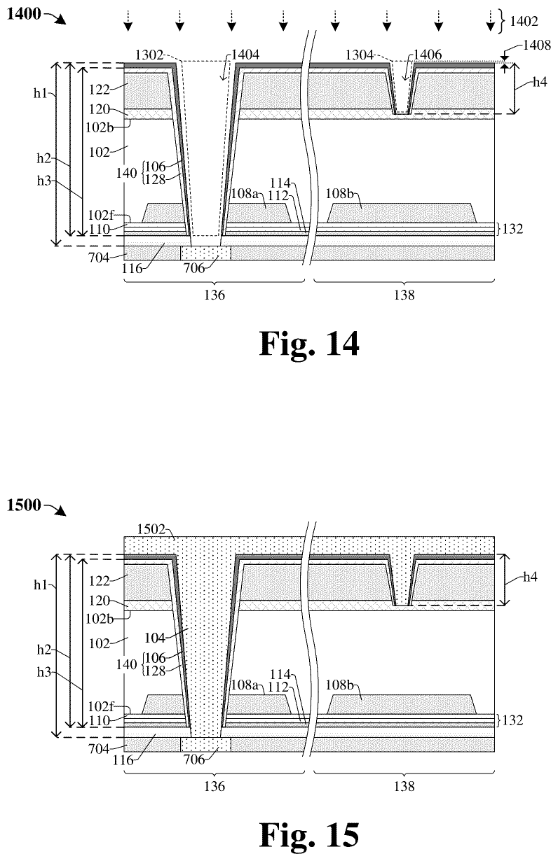

As illustrated in cross-sectional view 1500 of FIG. 15, a metal layer 1502 is formed over the second dielectric liner 106 and within the active TSV opening 1404 (of FIG. 14), and the dummy via opening 1406 (of FIG. 14). The metal layer 1502 is deposited according to a CVD process, PECVD process, ALD process, or some other suitable deposition or growth process. The metal layer 1502 can be or comprise one or more of coper, tungsten, aluminum, or another suitable metal. The metal layer 1502 is deposited in both the peripheral region 136 and the device region 138 extending along inner sidewalls of the second dielectric liner 106, inner sidewalls of the ILD layer 116, and contacting the wire 706 and the dielectric film 120. Furthermore, the metal layer 1502 is deposited on the exposed surface of the dielectric film 120.

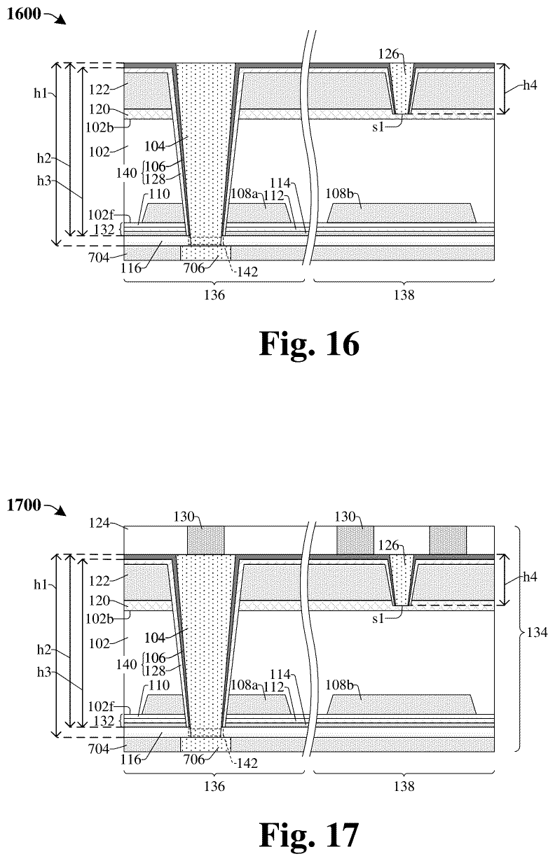

As illustrated in cross-sectional view 1600 of FIG. 16, a removal process is applied to the metal layer 1502 (of FIG. 15) to form an active TSV 104 and a dummy via 126. The removal process can be a planarization process, or etching process, that removes the metal layer 1502 (of FIG. 15) from the top surface of the second dielectric liner 106. After the removal process, the active TSV 104 is formed extending from the top surface of the second dielectric liner 106 to the top surface of the wire 706 within the peripheral region 136. After the removal process, the dummy via 126 is formed extending from the top surface of the second dielectric liner 106 to the exposed surface (of FIG. 14) of the dielectric film 120.

As illustrated in cross-sectional view 1700 of FIG. 17, an upper dielectric layer 124 is formed along a top surface of the second dielectric liner 106 and top surfaces of the active TSV 104 and dummy via 126. The upper dielectric layer 124 may be formed according to a deposition process such as CVD, PECVD, ALD, or the like. The upper dielectric layer 124 may be or comprise a nitride, a carbide, an oxide, a low-k dielectric, or the like. A plurality of wires 130 are formed within the upper dielectric layer 124. The plurality of wires 130 can be formed according to an etch (not shown) through a patterned photoresist (not shown) and subsequently filled with a metal layer (not shown) that extends through and over the upper dielectric layer 124 that is undergoes a planarization process to expose the upper dielectric layer 124. One of the plurality of wires 130 are formed contacting the top surface of the active TSV 104. Some of the plurality of wires 130 are formed within the upper dielectric layer 124 adjacent to but not contacting the dummy via 126 within the device region 138. The upper dielectric layer 124, the bond dielectric layer 704, and layers and features between the two define a device chip 134.

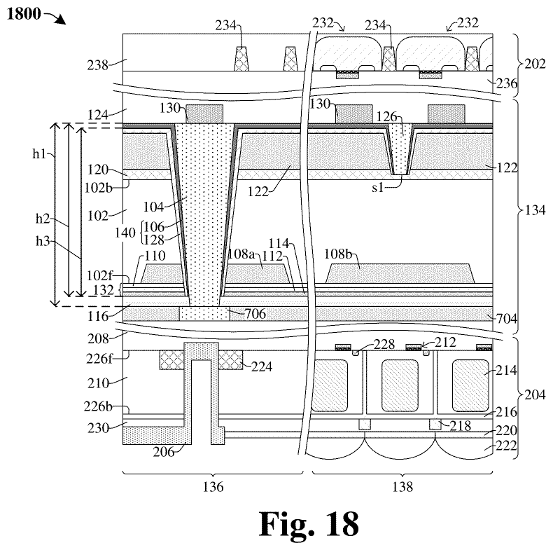

As illustrated in cross-sectional view 1800 of FIG. 18, a logic chip 202 and an imaging chip 204 are formed with active devices. The logic chip 202 is bonded to the top side of the device chip 134. The imaging chip 204 is bonded to the bottom side of the device chip 134. The logic chip 202 includes various features such as a plurality of logic devices 232, the imaging chip 204 includes various features such a plurality of photodetectors 214 as well as other features as discussed in accordance with FIG. 2.

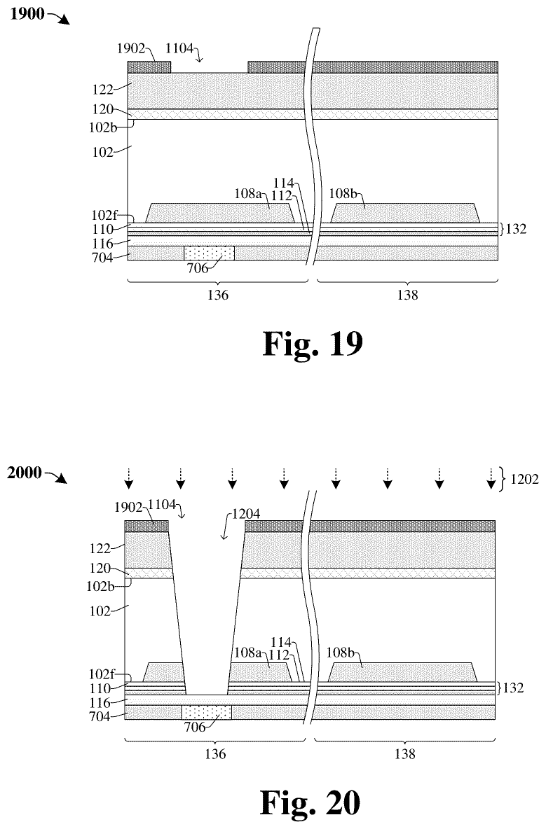

FIGS. 19-22 illustrate cross-sectional views 1900-2200 of alternative embodiments of a method of forming a stacked image sensor starting with an alternative embodiment relative to FIG. 11 where the active TSV opening and the dummy via opening are formed according to separate etches.

As illustrated in cross-sectional view 1900 of FIG. 19, a patterned photoresist 1902 is formed on the lower dielectric layer 122. The patterned photoresist 1902 is an alternative feature relative to the patterned photoresist 1102 of FIG. 11, where the patterned photoresist 1902 has a TSV opening 1104 formed over the lower dielectric layer 122 in the peripheral region 136 aligned over the wire 706. The patterned photoresist 1902 covers the device region 138.

As illustrated in cross-sectional view 2000 of FIG. 20, a first etch 1202 is performed through the TSV opening 1104 of the patterned photoresist 1902. The first etch 1202 forms an active TSV opening 1204 extending through the lower dielectric layer 122, the dielectric film 120, the device substrate 102, the STI structure 108a, and the plurality of dielectric layers 132 exposing a top surface of the ILD layer 116 over the wire 706. Aspects of the first etch 1202 that forms the active TSV opening 1204 are described in accordance with the first etch 1202 of FIG. 12.

As illustrated in cross-sectional view 2100 of FIG. 21, a patterned photoresist 2102 is formed over the lower dielectric layer 122 and within the active TSV opening 1204 (of FIG. 20). The patterned photoresist 2102 is formed with a dummy via opening 1106 within the device region 138.

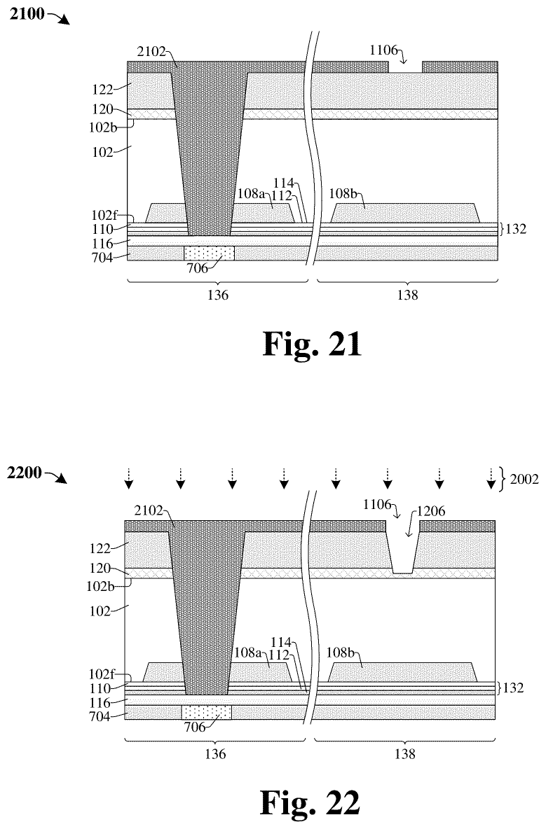

As illustrated in cross-sectional view 2200 of FIG. 22, a second etch 2002 is performed through the dummy via opening 1106 of the patterned photoresist 2102. The second etch 2002 forms a dummy via opening 1206 through the lower dielectric layer 122 and extends into the dielectric film 120 thereby exposing the dielectric film 120. Aspects of the dummy via opening 1206 are described in accordance with the dummy via opening 1206 of FIG. 12. After the second etch 2002, the patterned photoresist 2102 is removed (not shown) according to a removal process like a chemical wash process, an etch process, a planarization process, an ashing process, or other suitable removal process. After the removal process, a liner structure 140 is formed over the lower dielectric layer 122 and within the active TSV opening 1204 and dummy via opening 1206 according to the method steps of FIG. 13. Thereafter the stacked image sensor is formed according to aspects described in FIGS. 14-18.

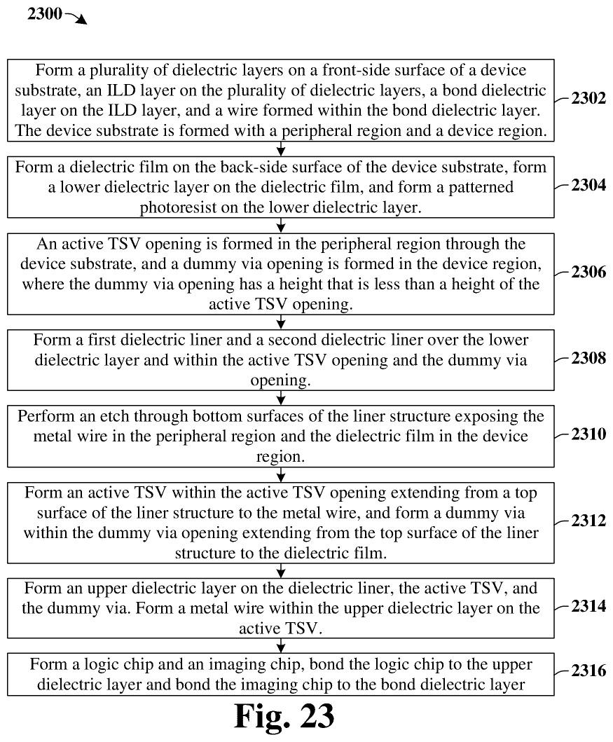

FIG. 23 illustrates some embodiments of a method 2300 of forming a stacked image sensor or semiconductor device comprising an active TSV within a peripheral region and a dummy via within a device region of a device chip. Although the method 2300 is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 2302, a plurality of dielectric layers are formed on a front-side surface of a device substrate. The device substrate has a peripheral region laterally offset from a device region. An ILD layer is formed on the plurality of dielectric layers. A bond dielectric layer is formed on the ILD layer and a wire is formed within the bond dielectric layer in the peripheral region. FIGS. 9-10 illustrate cross-sectional views 900-1000 corresponding to some embodiments of act 2302.

At act 2304, a dielectric film is formed on the device substrate, and a lower dielectric layer is formed on the dielectric film. A patterned photoresist is formed on the lower dielectric layer. FIGS. 11 and 19 illustrate cross-sectional views 1100 and 1900 corresponding to some embodiments of act 2304.

At act 2306, an active TSV opening is formed in the peripheral region and a dummy via opening is formed in the device region. The TSV opening is formed through the lower dielectric layer, the dielectric film, and the plurality of dielectric layers. The dummy via opening is formed through the lower dielectric layer and extends into the dielectric liner. The dummy via opening is formed with a height that is less than a height of the active TSV opening. FIGS. 12, 20, 21, and 22 illustrate cross-sectional views 1200, 2000, 2100, and 2200 corresponding to some embodiments of act 2306.

At act 2308, a liner structure comprising a first dielectric liner and a second dielectric liner are formed over the lower dielectric layer and within the active TSV opening and the dummy via opening. FIG. 13 illustrates cross-sectional view 1300 corresponding to some embodiments of act 2308.

At act 2310, an etch is performed through bottom surfaces of the liner structure exposing the metal wire in the peripheral region and the dielectric film in the device region. FIG. 14 illustrates cross-sectional view 1400 corresponding to some embodiments of act 2310.

At act 2312, an active TSV is formed within the active TSV opening extending from a top surface of the liner structure to the metal wire, and a dummy via is formed within the dummy via opening extending from the top surface of the liner structure to the dielectric film. FIGS. 15-16 illustrates cross-sectional views 1500-1600 corresponding to some embodiments of act 2312.

At act 2314, an upper dielectric layer is formed on the dielectric liner, the active TSV, and the dummy via. A metal wire is formed within the upper dielectric layer on the active TSV. FIG. 17 illustrates cross-sectional view 1700 corresponding to some embodiments of act 2314.

At act 2316, a logic chip is formed and an imaging chip is formed, the logic chip is bonded to the upper dielectric layer, and the imaging chip is bonded to the bond dielectric layer wherein the dummy via is electrically isolated from active devices. FIG. 18 illustrates cross-sectional view 1800 corresponding to some embodiments of act 2316.

Accordingly, in some embodiments, the present disclosure relates to a semiconductor device that has one or more dummy vias disposed within a device region and one or more active TSVs disposed in a peripheral region that laterally surrounds the device region. The one or more dummy vias are electrically isolated from active devices.

In some embodiments, the present disclosure relates to a semiconductor device having a device substrate with a front-side surface opposite a back-side surface, an upper dielectric layer over the back-side surface, an through substrate via (TSV) extending from the upper dielectric layer through the device substrate, and a dummy via laterally offset from the TSV. A top surface of the dummy via and a top surface of the TSV are substantially co-planar, and a bottom surface of the dummy via is separated from the front-side surface by the device substrate. The dummy via is electrically isolated from one or more active devices.

In some embodiments, the present disclosure relates to a semiconductor device, having an imaging chip, a logic chip; and a device substrate arranged between the logic chip and the imaging chip, the device substrate having a front-side surface opposite a back-side surface, wherein the device substrate has a peripheral region laterally separated from a device region. The semiconductor device further has an upper dielectric layer over the back-side surface, a wire disposed under the front-side surface within the peripheral region, a through substrate via (TSV) disposed within the device substrate, the TSV extending from the upper dielectric layer to the wire; and a dummy via disposed within the device region and extending from a bottom surface of the upper dielectric layer towards the device substrate. The dummy via is separated from the front-side surface of the device substrate, and a bottom surface of the dummy via is disconnected from a metal structure.

A method of forming a semiconductor device, the method including forming a lower dielectric layer over a back-side surface of a device substrate, wherein the device substrate has a front-side surface that is opposite the back-side surface, and the device substrate has a peripheral region laterally separated from a device region. The method includes forming a wire over a front-side surface of the device substrate within the peripheral region. The method includes performing one or more etches through a top surface of the lower dielectric layer. The one or more etches form a through substrate via (TSV) opening through the lower dielectric layer and the device substrate within the peripheral region. A bottom surface of the TSV opening is separated from the wire. The one or more etches form a dummy via opening extending into the lower dielectric layer within the device region. A bottom surface of the dummy via opening is above the front-side surface of the device substrate. The method includes forming a dielectric liner within the TSV opening and the dummy via opening. The method includes performing a second etch through the TSV opening that extends the TSV opening to a top surface of the wire. The method includes forming a metal layer within the TSV opening and the dummy via opening wherein the metal layer forms a TSV within the TSV opening and a dummy via within the dummy via opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a device substrate having a front-side surface opposite a back-side surface;
an upper dielectric layer over the back-side surface;
a through substrate via (TSV) extending from the upper dielectric layer through the device substrate; and
a dummy via laterally offset from the TSV, wherein a top surface of the dummy via and a top surface of the TSV are substantially co-planar, and a bottom surface of the dummy via is separated from the front-side surface by the device substrate.

2. The semiconductor device of claim 1, further comprising:
a lower device dielectric between the upper dielectric layer and the device substrate, and the dummy via is disposed within the lower device dielectric; and
a first dielectric liner, wherein the first dielectric liner is disposed between outer sidewalls of the TSV and the device substrate, and the first dielectric liner is disposed between outer sidewalls of the dummy via and the lower device dielectric.

3. The semiconductor device of claim 2, further comprising:
a second dielectric liner disposed along sidewalls of the TSV and the dummy via, wherein the second dielectric liner extends along inner sidewalls of the first dielectric liner separating the TSV and the dummy via from the first dielectric liner.

4. The semiconductor device of claim 3, wherein the first dielectric liner and the second dielectric liner are different materials with different etch rates.

5. The semiconductor device of claim 2, wherein the first dielectric liner directly contacts the bottom surface of the dummy via across an entirety of the bottom surface of the dummy via.

6. The semiconductor device of claim 1, further comprising:
a wire disposed within the upper dielectric layer, wherein the wire contacts the dummy via.

7. The semiconductor device of claim 1, further comprising:
a lower dielectric layer disposed under the upper dielectric layer, and a dielectric film disposed between the lower dielectric layer, wherein the TSV extends through the lower dielectric layer and the dielectric film, and the dummy via extends through the lower dielectric layer and into the dielectric film.

8. The semiconductor device of claim 7, further comprising:
an imaging device; and
a bond pad laterally offset from the imaging device, wherein the TSV is aligned over the bond pad and the dummy via is aligned over the imaging device.

9. A semiconductor device, comprising:
an imaging chip;
a logic chip; and
a device substrate arranged between the logic chip and the imaging chip, the device substrate having a front-side surface opposite a back-side surface, wherein the device substrate has a peripheral region laterally separated from a device region;
an upper dielectric layer over the back-side surface;
a wire disposed under the front-side surface within the peripheral region;
a through substrate via (TSV) disposed within the device substrate, the TSV extending from the upper dielectric layer to the wire; and
a dummy via disposed within the device region and extending from a bottom surface of the upper dielectric layer towards the device substrate, wherein the dummy via is separated from the front-side surface of the device substrate.

10. The semiconductor device of claim 9, further comprising a dielectric film disposed between the upper dielectric layer and the device substrate, wherein the bottom surface of the dummy via fully contacts the dielectric film.

11. The semiconductor device of claim 9, further comprising a lower device dielectric disposed between the upper dielectric layer and the device substrate, wherein the bottom surface of the dummy via fully contacts the lower device dielectric.

12. The semiconductor device of claim 9, wherein the bottom surface of the dummy via fully contacts the device substrate.

13. The semiconductor device of claim 9, wherein the TSV is one of a plurality of TSVs, and the dummy via is one of a plurality of dummy vias,
wherein the plurality of TSVs are disposed within the peripheral region, the plurality of dummy vias are disposed within the device region, and the plurality of TSVs surround an outer perimeter of the plurality of dummy vias.

14. The semiconductor device of claim 13, wherein the plurality of dummy vias are vertically separated from a plurality of active devices disposed within the device substrate in the device region.

15. The semiconductor device of claim 9, wherein the TSV and the dummy via extend from a common surface defined by a bottom surface of the upper dielectric layer, wherein a height of the TSV is greater than a height of the dummy via, and a width at a top surface of the TSV is greater than a width at a top surface of the dummy via.

16. A method of forming a semiconductor device, the method comprising:
forming a lower dielectric layer over a back-side surface of a device substrate, wherein the device substrate has a front-side surface that is opposite the back-side surface, and the device substrate has a peripheral region laterally separated from a device region;
forming a wire over a front-side surface of the device substrate within the peripheral region;
performing one or more etches through a top surface of the lower dielectric layer, wherein the one or more etches form a through substrate via (TSV) opening through the lower dielectric layer and the device substrate within the peripheral region, wherein a bottom surface of the TSV opening is separated from the wire, and wherein the one or more etches form a dummy via opening extending into the lower dielectric layer within the device region, wherein a bottom surface of the dummy via opening is above the front-side surface of the device substrate;
forming a dielectric liner within the TSV opening and the dummy via opening;
performing a second etch through the TSV opening that extends the TSV opening to a top surface of the wire; and
forming a metal layer within the TSV opening and the dummy via opening wherein the metal layer forms a TSV within the TSV opening and a dummy via within the dummy via opening.

17. The method of claim 16, further comprising:
receiving an imaging chip with one or more image sensors;
bonding the imaging chip to a device chip that comprises the lower dielectric layer, the device substrate, the wire, the TSV, and the dummy via;
receiving a logic chip with one or more active devices; and
bonding the logic chip to the device chip.

18. The method of claim 16, further comprising:
forming an inter-layer dielectric (ILD) layer between the device substrate and the wire;
performing the one or more etches that exposes a top surface of the ILD layer; and
performing an etch that extends the TSV opening through the ILD layer.

19. The method of claim 16, wherein forming the dielectric liner comprises:
forming a first dielectric liner along a top surface of the lower dielectric layer and through the TSV opening and the dummy via opening; and
forming a second dielectric liner on an exposed surface of the first dielectric liner and inner sidewalls of the first dielectric liner within the TSV opening and the dummy via opening.

20. The method of claim 19, wherein an etch is performed through bottom surfaces of the dielectric liner within the peripheral region and the device region.
